(19) United States
(12) Patent Application Publication
(10) Pub. No.: US 2020/0161444 A1
(43) Pub. Date: May 21, 2020

(54) Manufacturing Method of Diode

(71) Applicant: Cystech Electronics Corp., New Taipei City (TW)

(72) Inventor: Chu-Neng Shen, Zhubei City (TW)

(21) Appl. No.: 16/673,744

(22) Filed: Nov. 4, 2019

(30) Foreign Application Priority Data
Nov. 21, 2018 (TW) 107141520

(51) Int. Cl. H01L 29/66

(52) U.S. Cl. CPC H01L 29/6609

(57) ABSTRACT

A manufacturing method of a diode includes depositing an epitaxial layer and an oxidation structure on a substrate; etching the epitaxial layer to form active trenches and a termination trench using a configuration of the oxidation structure, wherein the termination trench has a first sidewall, a second sidewall, and a bottom portion; performing a thermal oxidation procedure to deposit a trench oxide layer to cover a sidewall and a bottom portion of each active trench, the first sidewall, the second sidewall, and the bottom portion; depositing a semiconductor layer on each active trench, the first sidewall, and the second sidewall to fill the semiconductor layer in each active trench and cover the first sidewall and the second sidewall; and depositing a metal silicide layer on each active trench, and covering the semiconductor layer of the first sidewall and the second sidewall by the metal silicide layer.

### CROSS-REFERENCE TO RELATED APPLICATION

This application claims priority from Taiwan Patent Application No. 107141520, filed on Nov. 21, 2018, in the Taiwan Intellectual Property Office, the content of which is hereby incorporated by reference in its entirety for all purposes.

### BACKGROUND OF THE INVENTION

### 1. Field of the Invention

The present invention relates to a manufacturing method of a diode, more particularly to a manufacturing method of a diode that has the advantage of simplifying the manufacturing process.

### 2. Description of the Related Art

With the advancement of the electronic technique and the trend of miniaturization of electronic products, the integrated-circuit manufacturing process is utilized to produce more and more electronic elements. However, several aspects have to be taken into consideration in terms of electronic elements manufactured with the integrated-circuit manufacturing process, such as the issues of voltage endurance, mutual interference, or anti-noise.

Specifically, a diode plays a crucial role in a circuit, as the diode is provided with the characteristics of forward-on and reverse-off. Due to the requirement of various diodes in the design of the circuit, the manufacturing method of the diode becomes complicated. How to solve the aforementioned issue has become a problem that needs to be addressed.

Accordingly, the inventor of the present invention has designed a manufacturing method of a diode in an effort to tackle deficiencies in the prior art and further to enhance the implementation and application in industries.

### SUMMARY OF THE INVENTION

In view of the aforementioned drawbacks, the present invention aims to provide a manufacturing method of a diode to solve the problem that may be encountered in the prior art.

On the basis of the purpose as mentioned above, the present invention provides a manufacturing method of a diode, including: (1) sequentially depositing an epitaxial layer and an oxidation structure on a substrate; (2) etching the epitaxial layer to form a plurality of active trenches and a termination trench by using a configuration of the oxidation structure, wherein the termination trench has a first sidewall, a second sidewall, and a bottom portion; (3) performing a thermal oxidation procedure to deposit a trench oxide layer to cover a sidewall and a bottom portion of each of the active trenches, and the first sidewall, the second sidewall, and the bottom portion of the termination trench; (4) depositing a semiconductor layer on each of the active trenches, and the first sidewall, and the second sidewall of the termination trench to fill in each of the active trenches with the semiconductor layer and to cover the first sidewall and the second sidewall with the semiconductor layer; and (5) depositing a metal silicide layer on each of the active trenches, and covering the semiconductor layer on the first sidewall and the second sidewall by the metal silicide layer. Compared to conventional techniques, the manufacturing method of a diode of the present invention may achieve simplification of the manufacturing procedure of a diode and lower the manufacturing cost by realizing the manufacture of a diode without the configuration of an insulating barrier.

Preferably, the manufacturing method of a diode of the present invention further includes defining the plurality of active trenches as an active region, wherein the first sidewall of the termination trench is close to the active region, and the second sidewall of the termination trench is away from the active region.

Preferably, the manufacturing method of a diode of the present invention further includes depositing a metal electrode on the metal silicide layer on the active trenches, and partially covering the metal silicide layer of the first sidewall and the second sidewall of the termination trench by the metal electrode.

Preferably, the manufacturing method of a diode of the present invention further includes depositing a back electrode on a bottom surface the substrate.

Preferably, the oxidation structure is formed by a plurality of oxidation masks.

Preferably, a width of the termination trench is greater than a width of each of the active trenches.

As stated above, the manufacturing method of a diode of the present invention may achieve the simplification of the manufacturing procedure of a diode and lower the manufacturing cost by realizing the manufacture of a diode without the configuration of an insulating barrier in comparison with the conventional techniques.

### BRIEF DESCRIPTION OF THE DRAWINGS

FIG. 1 depicts a flowchart of a manufacturing method of a diode of the present invention.

### DESCRIPTION OF THE PREFERRED EMBODIMENTS

The advantages, features, and technical methods of the present invention are to be explained in detail with reference to the exemplary embodiments and the accompanying drawings for the purpose of being easier to be understood. Moreover, the present invention may be realized in different forms, and should not be construed as being limited to the embodiments set forth herein. Conversely, for a person of ordinary skill in the art, the embodiments provided shall make the present invention convey the scope more thoroughly, comprehensively, and completely. In addition, the present invention shall be defined only by the appended claims.

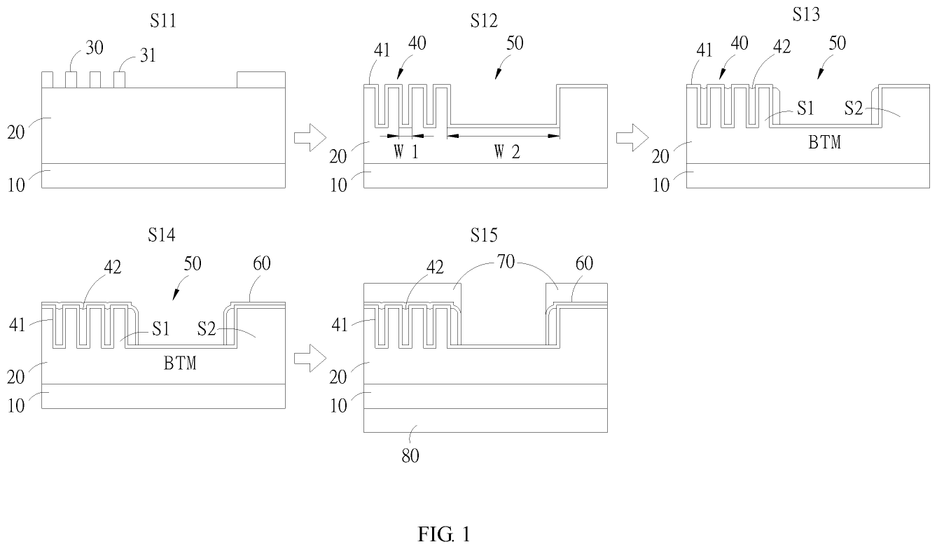

Please refer to FIG. 1, which depicts a flowchart of a manufacturing method of a diode of the present invention. As shown in FIG. 1, the manufacturing method of a diode of the present invention includes (1) Step S11: sequentially depositing an epitaxial layer 20 and an oxidation structure 30 on a substrate 10, wherein the oxidation structure 30 is formed by a plurality of oxidation masks 31, and the configuration of the oxidation structure 30 may be manufactured with optical masks; the spacing of each of the oxidation masks 31 may be varied according to the design of the diode, and thus the number and spacing of the oxidation masks 31 are not limited to what is illustrated in FIG. 1; (2) Step S12: etching the epitaxial layer 20 to form a plurality of active trenches 40 and a termination trench 50 by using the configuration of the oxidation structure 30, in which the positions of the plurality of active trenches 40 and the termination trench 50 may be defined by the configuration of the oxidation structure 30, and the plurality of active trenches 40 may be defined as an active region and the termination trench 50 may be defined as a termination region; wherein the termination trench 50 has a first sidewall S1, a second sidewall S2, and a bottom portion BTM, and the first sidewall S1 is close to the active region, and the second sidewall S2 is away from the active region; wherein the width W2 of the termination trench 50 is greater than the width W1 of each of the active trenches 40; where in the thermal oxidation procedure may be further performed to deposit a trench oxide layer 41 to cover a sidewall and a bottom portion of each of the active trenches 40, and to cover the first sidewall S1, the second sidewall S2, and the bottom portion BTM of the termination trench 50; (3) Step S13: depositing a semiconductor layer 42 on each of the active trenches 40, and on the first sidewall S1, and the second sidewall S2 of the termination trench 50, thereby filling in each of the active trenches 40 with the semiconductor layer 42 and covering the first sidewall S1 and the second sidewall S2 with the semiconductor layer 42; (4) Step S14: depositing a metal silicide layer 60 on each of the active trenches 40, and partially covering the semiconductor layer 42 on the first sidewall S1 and the second sidewall S2 by the metal silicide layer 60; and (5) Step S15: depositing a metal electrode 70 on the metal silicide layer 60 on the active trenches 40, partially covering the metal silicide layer 60 of the first sidewall S1 and the second sidewall S2 by the metal electrode 70, and depositing a back electrode 80 on the bottom surface of the substrate 10 opposite to the surface where the epitaxial layer 20 is deposited. Compared to conventional techniques, the manufacturing method of a diode of the present invention may achieve the simplification of the manufacturing procedure of a diode and lower the manufacturing cost by realizing the manufacture of a diode without the configuration of an insulating barrier.

It is noted that the deposition of the metal electrode 70 and the back electrode 80 may also be achieved by electroless plating. Specifically, since the configuration of the trench oxide layer 41 of the termination trench 50 has poor electrical conductivity of the trench oxide layer 41, the metal silicide layer 60 has a relatively high electrical conductivity. Therefore, by utilizing the method of electroless plating, the metal electrode 70 may be selectively deposited on the metal silicide layer 60 of the active trench 40 instead of being deposited on the trench oxide layer 41, and the back electrode 80 may be deposited on the bottom surface of the substrate 10.

In addition, the diode manufactured by the method of the present invention may be set as follows: In this embodiment, the substrate 10 may be a silicon substrate, the epitaxial layer 20 may be n-type or p-type, and the n-type and p-type are realized by adding impurities into the semiconductor material. The semiconductor material may be silicon, and the impurities may be selected from the Group III element or the Group V element. The process of adding impurities may be realized by the method of diffusing impurities in the semiconductor material at a high temperature through ion implantation, a solid diffusion source, or a liquid diffusion source. The material of the semiconductor layer 42 may include polysilicon, and the material of the trench oxide layer 41 and the plurality of oxidation masks 31 includes oxide (SiO₂). The metal silicide layer 60 may be formed by metal silicide; the metal material of the metal silicide layer 60 and the material of the metal electrode 70 and the back electrode 80 may include at least one of materials such as indium (In), tin (Sn), aluminium (Al), gold (Au), platinum (Pt), Zinc (Zn), germanium (Ge), silver (Ag), plumbum (Pb), palladium (Pd), copper (Cu), beryllium gold (AuBe), beryllium germanium (BeGe), nickel (NI), plumbum tin (PbSn), chromium (Cr), zinc gold (AuZn), titanium (Ti), tungsten (W), titanium tungsten (TiW), and the like.

Accordingly, compared to conventional techniques, the manufacturing method of a diode of the present invention may achieve the simplification of the manufacturing procedure of a diode and lower the manufacturing cost by realizing the manufacture of a diode without the configuration of an insulating barrier. The method of the present invention may be applied to the manufacturing industries of semiconductors.

The above description is merely illustrative rather than restrictive. Any scope without departing from the spirit of the present invention as to equivalent modifications or alterations are intended to be included in the following claims.

What is claimed is:

1. A manufacturing method of a diode, comprising:
depositing an epitaxial layer on a substrate;
depositing an oxidation structure on the epitaxial layer;
etching the epitaxial layer to form a plurality of active trenches and a termination trench by using a configuration of the oxidation structure, with the termination trench having a first sidewall, a second sidewall, and a bottom portion;
performing a thermal oxidation procedure to deposit a trench oxide layer to cover a sidewall and a bottom portion of each of the active trenches, and the first sidewall, the second sidewall, and the bottom portion of the termination trench;
depositing a semiconductor layer on each of the active trenches, and the first sidewall, and the second sidewall of the termination trench to fill each of the active trenches with the semiconductor layer and to cover the first sidewall and the second sidewall with the semiconductor layer; and
depositing a metal silicide layer on each of the active trenches, and covering the semiconductor layer on the first sidewall and the second sidewall by the metal silicide layer.

2. The manufacturing method of the diode according to claim 1, further comprising defining the plurality of active trenches as an active region, wherein the first sidewall of the termination trench is close to the active region, and the second sidewall of the termination trench is away from the active region.

3. The manufacturing method of the diode according to claim 1, further comprising depositing a metal electrode on the metal silicide layer on the active trenches, and partially covering the metal silicide layer on the first sidewall and the second sidewall of the termination trench by the metal electrode.

4. The manufacturing method of the diode according to claim 1, further comprising depositing a back electrode on a bottom surface of the substrate.

5. The manufacturing method of the diode according to claim 1, wherein the oxidation structure is formed by a plurality of oxidation masks.

6. The manufacturing method of the diode according to claim 1, wherein a width of the termination trench is greater than a width of each of the active trenches.
